(19) United States
(12) Patent Application Publication
(10) Pub. No.: US 2017/0117725 A1
(43) Pub. Date: Apr. 27, 2017

(54) Thermal Monitoring of Battery Packs

(71) Applicant: Oxfordian, LLC, Dallas, TX (US)

(72) Inventors: Christopher Hendricks, Catonsville, MD (US); Michael G. Pecht, Hyattsville, MD (US); Abbas Tourani, Coventry (GB)

(21) Appl. No.: 15/330,603

(22) Filed: Oct. 18, 2016

Related U.S. Application Data
(60) Provisional application No. 62/245,397, filed on Oct. 23, 2015.

(51) Int. Cl. H02J 7/00; G01K 3/14; G01R 31/36; G01K 1/02

(52) U.S. Cl. CPC H02J 7/0026; G01K 1/026; G01K 3/14; G01R 31/3675

(57) ABSTRACT

A computer-aided health monitoring method is described for thermal monitoring of a battery pack that consists of using modeling to determine temperature distributions representative of safe battery operating conditions and a technique is described for comparing sensor measurements to a look-up table of the pre-modeled temperature profiles under various operating conditions. In one embodiment a simplified model of temperature distribution is described.

### FIELD OF INVENTION

The present invention relates to health monitoring of a battery pack by assessing the operational temperatures of the pack with respect to expected thermal profiles. In some embodiments the battery pack includes integrated thermal sensors for determining the thermal profile of the battery pack at any given ambient temperature, and then comparing the measured profile to thermal profiles stored in the memory of a battery management system, said thermal profiles established under varying ambient temperature conditions either empirically or through a fully simulated design of experiments. An alert is issued when an excursion from normal is detected.

### BACKGROUND OF THE INVENTION

A battery system describes a host device, its battery pack(s), and any other components used to support the operation of the device. The battery pack(s) can be used for primary or backup power for stationary or nonstationary applications. The battery types in common use today include but are not limited to lead-acid, nickel cadmium, nickel-metal hydride, and lithium-ion based. Each battery pack type may exhibit different failure mechanisms under a variety of operating conditions; however, thermal abuse can damage any type of battery pack and lead to a safety risk.

A battery pack can be used as an energy storage device for a number of applications including, but not limited to, portable consumer electronics, electric vehicles (EVs), and unmanned autonomous vehicles. A battery pack can consist of one or more battery cells connected in parallel and series configurations to provide adequate voltage and current based on the given application.

If a cell is mechanically damaged, overcharged, over-discharged, charged or discharged at a high rate, exposed to excessive heat, or externally short circuited, or if it develops an internal short circuit, it can vent, explode, or catch fire, affecting neighboring cells and possibly leading to cascading failures. In addition, the battery performance and cycle life are impacted by the operating temperature of the battery [1]. Therefore, it is necessary to keep the battery pack operating within specific limits through monitoring, control strategies, thermal management, or any other means of keeping the pack from undergoing thermal runaway.

If a battery is operating at low temperatures, it may experience reduced performance. Additionally, in the case of lithium-ion batteries, dendritic structures can form, resulting in internal short circuits. This could lead to thermal runaway if undetected. The cell's temperature could be elevated; however, due to a cold ambient environment, where a simple thermal strategy may initially fail to detect conditions leading up to thermal runaway.

Battery packs consisting of multiple cells with air-gaps or filler material may exhibit complex thermal profiles. Depending on the heat transfer characteristics within the pack, the temperature in the center of the pack can vary significantly from the edges of the pack. Changes in the ambient environment can impact the temperature profiles.

The temperature profile within the battery pack can most accurately be modeled using a physics-based model that simulates the internal electrochemical states of a battery by describing the thermodynamics, charge-transfer kinetics, and mass transport limitations of the various reactions [2]. Physics-based models can be useful tools for battery cell designers; however, the solution of the coupled partial differential equations describing battery behavior is time-consuming [2] and thus difficult to use in real time for a BMS. For lithium-ion batteries, for example, first principles models have been developed to study the electrochemical [3], mechanical (including particle fracture and electrode damage) [4-9], and thermal behavior of the battery cells [10-11]. In addition, models were also developed to study the thermal behavior of the cell in order to determine the heat generation terms in an energy balance equation [12, 13]. Similar models can be developed to describe the unique failure mechanisms of other battery chemistries including, but not limited to, lead-acid, nickel cadmium, and nickel-metal hydride.

The heat generation inside battery cells is a complex process based on the electrochemical reaction rates that are dependent on the battery's state of charge (SOC) and internal temperature. Heat is generated in battery cells from three fundamental sources of activation (interfacial kinetics), concentration (species transport), and Ohmic (Joule heating from the movement of charged particles) losses [14]. By applying the first law of thermodynamics around the cell control volume, excluding current collectors, and making numerous simplifications, Bernardi et al. derived an equation for heat generation inside the battery [15]. The heat generation term also can be obtained by an empirical equation. Newman and Tiedemann [16] proposed an equivalent equation that is frequently cited in the literature.

Thermal runaway is an escalating series of reactions that occur in battery cells. In lithium-ion cells, thermal runaway was modeled by adding a heat source term in the energy balance equation. Kim, Pesaran, and Spotnitz [17] developed a thermal runaway model by considering the heat generated from decomposition reactions in the solid electrolyte interface and electrolyte decomposition. Guo et al. [18] studied the thermal runaway behavior of high-capacity lithium-ion batteries for EV applications. They developed a three-dimensional thermal model to study the temperature distribution under abuse conditions. A thermal runaway model for alternate battery chemistries, including lead-acid, nickel cadmium, and nickel-metal hydride, could also be developed to predict the operating conditions under which the battery should not operate.

Whether simulating thermal runaway or the thermal profile within a battery pack experiencing typical usage conditions, the models are limited to offline use rather than within a BMS. The use of a detailed model in an offline process to build a look-up table or equation (simplified relationship describing the temperature as a function of pack location, operating conditions, and boundary conditions) for on-board applications bypasses the limitations of physics-based battery models. In its simplest form, a look-up table consists of rows of spatial coordinates and temperatures. One or more look-up tables could be created for different operating conditions, with acceptable temperature extremes defining the boundary conditions. Alternately, an equation can be constructed that takes inputs of the spatial coordinates, operating and boundary conditions, and outputs the expected temperature. This equation can be a phenomenological relationship between variables, a reduced-order physics-based model, or even a statistical or machine learning model.

A battery system with integrated thermal management as described can be utilized to perform anomaly detection, diagnostics, or prognostics of battery packs. Anomaly detection uses algorithms to simply identify whether the pack is undergoing typical or anomalous operating conditions. If an anomaly is detected, the BMS should provide guidance/recommendations based on the severity of the anomaly. Diagnostics takes anomaly detection a step further and pinpoints the location and cause of the anomaly. Diagnostics can aid in identifying the root cause of a failure or can aid in maintenance. Prognostics aids in predicting the onset of failure and can provide advanced warning before a pre-determined failure threshold. All of the above can be used to improve safety or performance, reduce costs, and prolong the useful life of a battery.

In conjunction with predicting temperature distribution by models, thermal sensors can be used to detect local temperatures within the battery cell/pack Error! Reference source not found.; however, they can add to the cost, weight, and complexity of the battery pack and are susceptible to failure themselves. In large battery packs, sub-optimal placement of temperature sensors could delay the detection of a thermal event. Therefore, it is necessary to optimize the location and the number of temperature sensors to maximize the safety of the pack. Several prior works have identified the need for thermal sensors within a battery pack.

U.S. Pat. No. 8,487,588 B2 describes a battery pack consisting of cells, thermal sensors, and controllers to convert the thermal measurement to an electrical signal. U.S. Pat. No. 8,620,506 B2 discloses a controller to regulate the temperature of a battery within an operating temperature. However, the optimization of the number of sensors and anomaly detection methods are not discussed.

The presence of thermal sensors alone does not provide adequate safety for a battery pack. U.S. Patent 2011/0090666 A1 reports mounting arrangements for thermal sensors in a battery pack. The claim focuses on sensor placement for streamlining the manufacturing process, but does not relate to sensor placement for control or battery management purposes. U.S. Pat. No. 8,084,154 B2 discloses a battery pack thermal management apparatus and methodology. The prior work determines whether the battery needs to be heated based on temperature measurements and comparing the measurements to the current operating conditions. Safety and the risk of thermal runaway are not considered. U.S. Patent 20140067297 describes a method for optimally managing the temperature of an electrochemical storage system based on an online or offline model to prevent risks of thermal runaway. However, this method does not discuss an approach to optimal sensor placement or the number of sensors optimally needed to estimate temperature distributions.

### SUMMARY OF THE INVENTION

The present invention is a battery pack with integrated thermal management that is built upon laboratory experiments or a full simulated design of experiments (DOE) for developing thermal profiles in batteries under a wide-range of operating conditions. The thermal profiles are embedded in the battery management system in the form of look-up tables or equations and compared to sensor measurements to determine deviations from healthy behavior.

### BRIEF DESCRIPTION OF THE DRAWINGS

The present invention is described with respect to particular exemplary embodiments thereof and reference is accordingly made to the drawings in which:

FIG. 1 is a schematic illustrating a battery pack with temperature sensors.

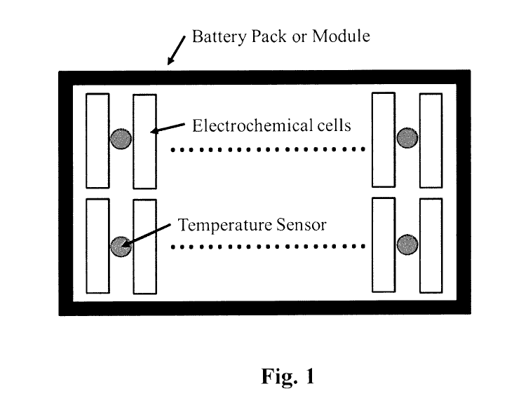

FIG. 2 is a schematic of a battery pack with sensors at discrete locations reflected in a coordinate system for a look-up table or equation.

FIG. 3 is a flow chart for implementation of thermal modeling and sensing for battery anomaly detection and health assessment.

FIG. 4 is a schematic of both a battery pack with batteries connected in series (FIG. 4A), and in parallel (FIG. 4B).

FIG. 5 is a plot of temperature measurements for three test samples at different discharge rates.

FIG. 6 is a plot comparing temperatures from a computer-aided modeled result vs measured battery cell temperature.

### DETAILED DESCRIPTION OF THE INVENTION

Temperature monitoring and modeling are not limited to anomaly detection and safety. This same strategy can be used for many purposes including, but not limited to, the design of control strategies, implementation of active thermal management, assessment of the remaining useful life of the battery, or determination of warranty coverage.

A general example of the embodiments of the invention is described below with reference to the accompanying drawings. The invention is not limited to the construction set forth and may take on many forms embodied as both hardware and/or software. The invention may be embodied as an apparatus, a system, a method, or a computer program. The numbers are used to refer to elements in the drawings.

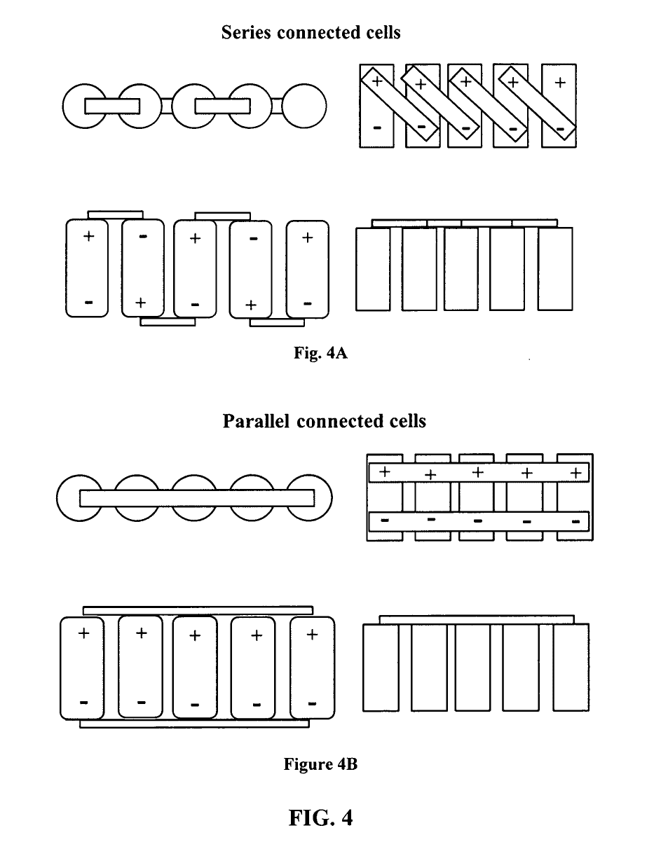

A battery pack is composed of at least one or more cells connected in various series and parallel combinations, such as shown in FIGS. 4A and 4B. In some embodiments individual cells are in the form of flat plate-like structures, which can be stacked to form the battery pack. In other embodiments the batteries can be cylindrical and stacked side by side. In some embodiments the battery packs pay be passively cooled, such as by air. In other embodiments they can be actively cooled such as by passing air over the pack or enclosing the pack through which enclosure cooling fluids are passed.

The cells can have different locations within the battery pack. It is to be noted that placement of cells within a battery pack can influence temperature fluctuations at different locations within the battery pack. If there is an obstruction in the cooling line between groups of cells, the inefficient cooling could be detected through the abnormal temperature distribution. With reference to FIG. (1), in one embodiment, there will be at least one temperature sensor for each cell in the battery pack. However, the invention is not limited to this case, and depending on the costs or ease of placing sensors, more or fewer sensors can be used. Furthermore, in some cases, cells may be made with embedded sensors.

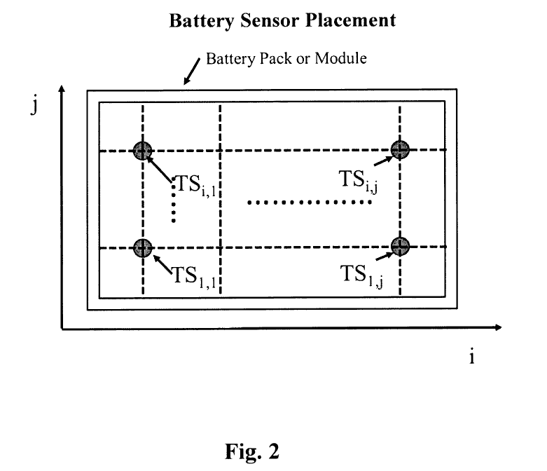

The temperature sensors used in the battery pack could be thermistors, infrared thermocouples, or any other variation of a digital or analog temperature measurement device. Multiple temperature sensor placement is shown in FIG. 2. Also important is to determine the number of sensors required to achieve a predefined level of temperature resolution in the battery pack. The level of temperature resolution can be determined through computer-aided modeling to assess detection times for different abusive or non-ideal operating conditions.

The process can be implemented within an existing battery management system (BMS) or contained on a separate microcontroller chip. The temperature measurements serve as inputs to the controller where they can be compared to the stored look-up table or equation. If the matched temperature distribution is not representative of a healthy operating condition, the microcontroller can relay that information to the user and/or take corrective action.

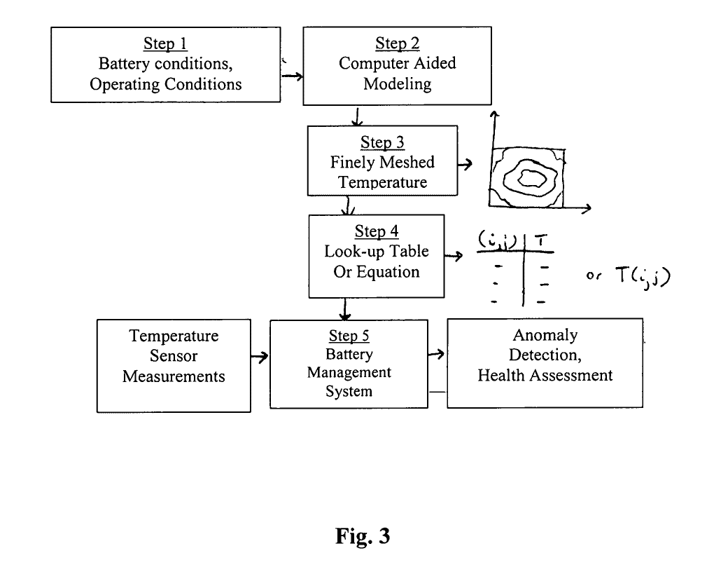

With reference to the development methodology depicted in FIG. 3, the first aspect of the method of this innovation involves creation in step 1 of a look-up table (or a set of equations, or plots) that determine how a set of boundary and operating conditions will affect the temperature distribution of the cells within the battery pack. This can be accomplished by considering all of the possible conditions of use; however, a subset of conditions of use can also be studied and a look-up table constructed. For example, various fixed intervals of boundary conditions can be assessed and used with various operating conditions. The number of conditions modeled is not limited by the number of expected use conditions; rather, the number of conditions modeled could be greater than or less than the number of expected use conditions.

By way of example, for a given battery pack, it is necessary in development of the look-up table to first determine the environment in which the pack is to be placed during use and to recreate the condition. Thus, if the battery pack is to be actively cooled, it should be placed in the coolant environment. The pack is then run and temperature profiles developed over a range of operating temperatures to establish a temperature profile at normal operating temperatures. If the pack is to be air cooled, then the lookup table is created using a range of outside air temperatures, including the extremes of temperatures that the battery is expected to encounter. If the expected operating range is 100 degrees centigrade, for example, then a profile can be established for a number of temperatures over the interval, such as at every 5 degrees C. or 10 degrees C., etc.

Computer-aided modeling (step 2) can be used to initially assess the effects of boundary and operating conditions on the battery pack's temperature distribution. A number of computer-aided modeling tools can be used including, but not limited to, computational fluid dynamics (CFD) software, finite element analysis (FEA) software, or other numerical methods for determining heat generation and dissipation. The battery's geometry, material properties, and constraints are imposed on the model to determine the heat transfer within a given system. Depending on the configuration of the cells and presence of active or passive thermal management, different temperature distributions will arise as a function of use. This can provide in step 3 a mapping of the battery pack's temperature distribution into a grid system that can be either finely or coarsely meshed, depending on the application requirements.

Finite element modeling is a numerical technique for approximating the solution of complex mathematical problems. Often, the equations describing physical phenomena, such as heat transfer or fluid mechanics, require the use of the finite element method because an exact analytical solution is not available. The desired solution area is subdivided into smaller entities, or elements, and these elements are connected through shared nodes. The elements can take on a variety of shapes including tetrahedra, rectangles, quadrangles, and bricks. The partial differential equations representing the physical phenomena of interest are then approximated for each node with sets of algebraic or ordinary differential equations. These equations are then combined for the entire solution area and solved to obtain an approximate solution for the problem. The finite element method is well studied and the errors introduced by the approximations are quantifiable.

Finite element modeling is computationally expensive, and often is utilized in finite element analysis of systems to predict the response of a structure or environment to stresses prior to the manufacturing process; however, the use of finite element modeling coupled to sensor systems for prognostics and health management purposes has not been established.

A full design of experiments (DOE) can be simulated using commercial or proprietary finite element software. The geometry of the battery pack is modeled, and any number of expected boundary conditions are applied to the model. The output of the finite element model can be temperature, temperature gradients, or any other number of heat transfer phenomena. In one embodiment, the temperatures at desired sensor locations in step 4 are saved for each set of boundary conditions and stored in a look-up table.

Using the look-up table, it is possible to interpolate between the points in the subset or extrapolate beyond the points to obtain an estimate of the temperature conditions in the battery pack. The results from the model can also be used to construct an equation to replace a look-up table. The equation could be linear, polynomial, logarithmic, or any other mathematical relationship that takes inputs of one or more locations (for example, x and y coordinates in or surrounding the battery pack) and the battery pack's operating and boundary conditions. The output of the model would be an expected temperature at a given location. The look-up table or set of equations can then be used to estimate the temperature at various locations in the battery pack. In one embodiment, there will be at least one temperature sensor for each cell in the battery pack. However, the invention is not limited to this case, and, depending on the costs or ease of placing sensors, more or fewer sensors can be used. Furthermore, in some cases, cells may be made with embedded sensors.

The look-up table in step 5 can be implemented within an existing BMS, contained on a separate microcontroller chip, or stored in external memory that can be accessed by a microcontroller. The temperature sensors used in the battery pack and/or at the boundary conditions could be thermistors, infrared thermocouples, or any other variation of a digital or analog temperature measurement device. In the case of a thermocouple, two dissimilar metal wires are placed into contact at the measurement point. The other end of the wires are connected to a microcontroller or data acquisition device where the voltage difference between the two wires is measured. This voltage difference can be mapped to a temperature based on the type of thermocouple used. Other thermal measurement techniques could be used and communicate the temperature based on individual operating principles. The temperature measurements serve as inputs to the controller where they can be converted into electrical signals representing temperature and compared to the stored look-up table or equations. The look-up table or equations can contain normal and abnormal temperature distributions for a variety of boundary and operating conditions, and the temperature measurements can quickly be matched to a stored temperature distribution.

If the sensed temperature distribution is not representative of a healthy operating condition, the microcontroller can relay that information to any number of individuals including, but not limited to, the user, the manufacturer, and/or emergency personnel. The microcontroller can then interact with other parts of the BMS, including the thermal management system, and take corrective action. For example, if the values differ by a certain amount or percentage or if this percentage changes in a certain manner with time, then it could signify an anomaly, with some decision support, a reliability or safety problem, and/or halt further battery operation. In some embodiments, the trigger for reporting an anomaly can be established using a machine learning algorithm, statistics, rules derived from experiments, or data analytics.

In another implementation, the temperature distribution can be used to assess the health or performance of the entire battery pack, as well as individual cells for maintenance actions. At elevated temperatures, the battery can degrade at an accelerated rate. This information could be relayed to the user, the manufacturer, the dealer, or any other individual. The information can also be stored in memory for warranty, maintenance, or resale purposes.

The operating conditions can be used to identify the appropriate look-up table or equation that should be used to assess the state of the battery. Using sensor inputs to measure the operating temperature, the pack voltage, pack current, and any other relevant boundary conditions, the most applicable look-up table or equation can be accessed from storage. Using pattern recognition and health management algorithms, such as neural networks or support vector machines, one can then assess the health and/or safety of the battery system, including all the cells of the battery pack.

In the simplest approach this assessment might be just a comparison of an estimated temperature given specific operating conditions against a measured value of temperature, such as the outside temperature as a reference temperature. Health and/or safety assessment of the pack or individual cells could be incorporated into the algorithms ahead of time by adjusting the computer-aided design models to account for degradation of the battery system, battery pack, or battery cell and changes in the temperature distribution as the batteries age. These changes can be further verified with experimental tests using different combinations of aged and healthy cells to create a large database of look-up tables or equations. As the temperature distributions change over time under known operating conditions, the health and/or safety of the cell or pack can be assessed in conjunction with other health-related battery information such as discharge capacity and internal resistance. A graphical user interface can be incorporated into a system that informs users of the effect of their usage patterns on the battery's degradation. Users can decide whether to alter their behavior to prolong battery life.

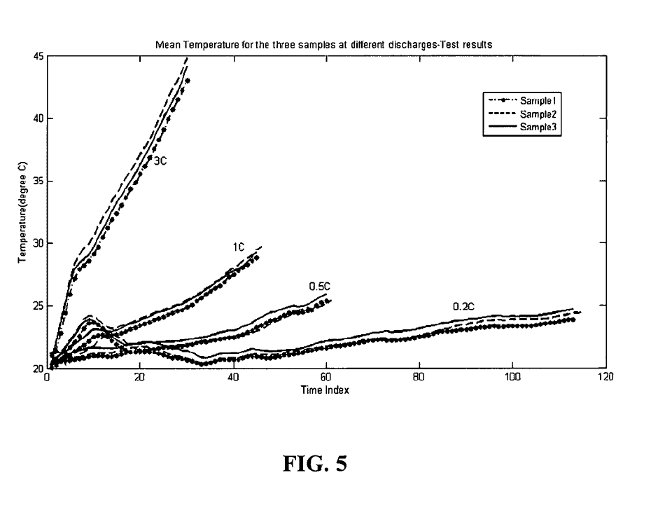

FIG. 5 represents experimental temperature data collected from three different samples of the same lithium-ion battery pouch cell. At different usage conditions (discharge rate given as a multiple of the battery's capacity, C), the battery undergoes time variant temperature changes. These changes in the cell's thermal behavior can affect the thermal profile in the battery pack and are captured in the offline modeling to build the look-up table or equation.

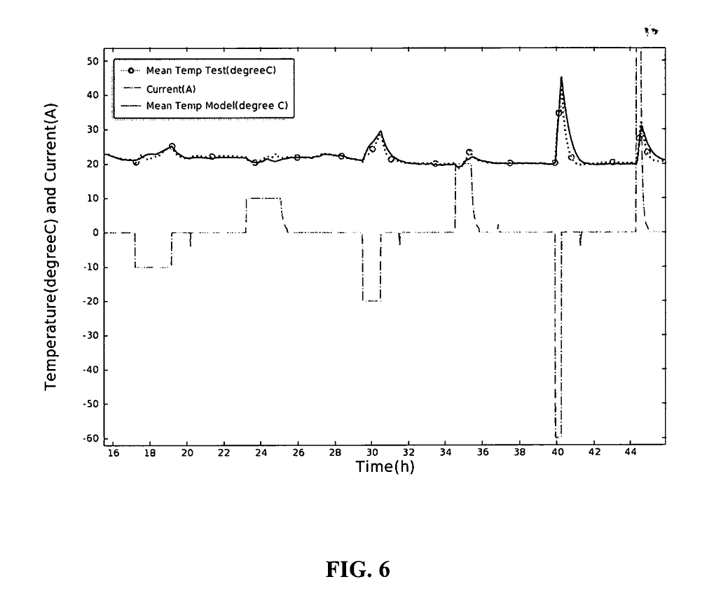

FIG. 6 demonstrates that the modeled results for a cell accurately match experimentally obtained cell temperatures during discharge and charge at a variety of rates. Computational modeling of a battery pack can be used to predict the thermal profile variations when the cell is in use by defining the appropriate boundary conditions and use profiles.

The methods of the invention can be extended to optimal control of battery charging procedures. In many applications, rapid charging may be desirable. Knowledge of predetermined temperature distributions could be used to accelerate charging while maintaining the battery in a safe temperature range. Deviations from predicted temperature distributions can be used to alter the charging profile or enable active thermal management strategies to continue charging at a high rate.

Additionally, the methods described herein can be extended in fleet applications by identifying similar aging trends across the fleet and using the information to perform over-the-air (OTA) BMS updates to the temperature look-up tables and equations. Outlier systems can be identified and investigated (through physical maintenance or life cycle history analysis) to determine the source of error

Finally, the methods described herein can be used to guide condition-based maintenance strategies, notify first responders of potential safety issues, or implement safety measures. For example, the localization of a fault can be used to direct thermal management to the fault location or to cause the BMS to discharge surrounding batteries to lower the impact of cascading failures.

The approach could be extended to diagnostics and localization of unhealthy or faulty cells. If the temperature distribution does not match any of the modeled temperature distributions, a built-in test function could be enabled to test the internal resistance or voltage of each cell, or a subset of cells, individually. This approach could assist in determining if the anomaly is safety-critical (excessive temperature due to a short circuit) or simply a performance issue (higher internal resistance leading to joule heating). Additionally, it could be used to localize heat zones that are receiving insufficient cooling. If there is an obstruction in the cooling line between groups of cells, the inefficient cooling could be detected through the abnormal temperature distribution.

### REFERENCES

[1] A. Tourani, P. White, P. Ivey, J. Power Sources. 268 (2014) 301-314.
[2] R. Rao, S. Vrudhula, D. N. Rakhmatov, Computer. 36 (2003) 77-87+4.
[3] V. Srinivasan, C. Y. Wang, J. Electrochem. Soc. 150 (2003) A98-A106.
[4] X. Xiao, W. Wu, X. Huang, J. Power Sources. 195 (2010) 7649-7660.
[5] M. Xiao, S. Choe, J. Power Sources. 218 (2012) 357-367.
[6] J. Christensen and J. Newman, “Stress generation and fracture in Lithium insertion materials,” Journal of Solid State Electrochem Vol. 10 (2006) pp. 293-319.
[7] J. Christensen and J. Newman, “A mathematical model of stress generation and fracture in Lithium Manganese Oxide,” Journal of the Electrochemical Society Vol. 153 Issue 6 (2006) pp. A1019-A1030.
[8] X. Zhang, W. Shyy, and A. M. Sastry, “Numerical simulation of intercalation-induced stress in Li-ion battery electrode particles,” Journal of The Electrochemical Society Vol. 154 (2007) pp. A910-A916.
[9] S. Renganathan, G. Sikha, S. Santhanagopalan, and R. E. White, “Theoretical analysis of stresses in a Lithium-ion cell,” Journal of The Electrochemical Society Vol. 157 (2010) pp. A155-A163.
[10] W. B. Gu, C. Y. Wang, J. Electrochem. Soc. 147 (2000) 2910-2922.
[11] W. Fang, O. J. Kwon, C.-. Wang, Int. J. Energy Res. 34 (2010) 107-115.
[12] X. Zhang, A. M. Sastry, W. Shyy, J. Electrochem. Soc. 155 (2008) A542-A552.
[13] M. Xiao, S. Choe, J. Power Sources. 241 (2013) 46-55.
[14] T. M. Bandhauer, S. Garimella, T. F. Fuller, J. Electrochem. Soc. 158 (2011) R1-R25.
[15] D. Bernardi, E. Pawlikowski, J. Newman, Journal of Electrochemical society. 132 (1985) 5.
[16] J. Newman, W. Tiedemann, AIChE J. 21 (1975) 25-41.
[17] G.-. Kim, A. Pesaran, R. Spotnitz, J. Power Sources. 170 (2007) 476-489.
[18] G. Guo, B. Long, B. Cheng, S. Zhou, P. Xu, B. Cao, J. Power Sources. 195 (2010) 2393-2398
[19] A. Tourani, P. White, P. Ivey, Journal of Power Sources. 255 (2014) 360-367.

What we claim is:

1. A method for monitoring the health of a battery system during charge, discharge, or rest comprising:
providing one or more electrically connected battery packs, wherein within each battery pack includes battery cells and at least one integrated temperature sensor;
providing means for converting the output from said sensors into electrical signals;
providing additional temperature sensors for measuring the external temperature of said one or more battery packs as an external reference temperature;
providing a battery management system which converts the electrical output of said sensors into temperature readings, thus establishing a temperature profile of the battery pack during charge, discharge, or rest, said battery management system further including a memory, which memory contains a database of predefined normal operating temperature profiles for said one or more battery packs over a variety of external reference temperatures,
comparing said temperature profile of said one or more battery packs during charge, discharge, or rest with the healthy thermal profile of said battery pack(s) at the measured external reference temperature; and,
issuing an alert should a sensor within the battery pack detect an excursion from normal operating temperature during such charge, discharge, or rest.

2. The method of claim 1 wherein the database containing predefined normal operating temperature profiles for a variety of external reference temperatures and use conditions comprises a look-up table of thermal profiles for said one or more battery packs, said profiles determined experimentally or through computer-aided simulation by generating a series of discrete thermal profiles for the packs for a select interval of temperatures over an expected range of operating temperatures.

3. The method of claim 1 wherein the database containing predefined normal operating temperature profiles for a variety of external reference temperatures comprises a set of equations, plots, or tables stored in said memory.

4. The method of claim 1 whereby a deviation from healthy triggers an alarm and halts further battery operation.

5. The method of claim 4 wherein the deviation from healthy can be based on a percentage change, the output of a machine learning algorithm, statistics, rules derived from experiments, or data analytics models.

6. The method of claim 1 wherein one or more battery packs are passively cooled.

7. The method of claim 1 wherein one or more battery packs are actively cooled.

8. The method of claim 1 wherein a temperature sensor is placed external to the housing of the battery system.

9. The method of claim 1 wherein each battery contained within said one or more battery packs has at least one thermal sensor.

10. The method of claim 2 wherein each of said look-up tables comprises rows of spatial coordinates and temperatures at an associated external reference temperature.

11. A method for monitoring the health of a battery system during charge, discharge, or rest comprising:
providing one or more electrically connected battery packs, wherein within each battery pack includes battery cells and at least one integrated temperature sensor;
providing means for converting the output from temperature sensors into electrical signals;
providing additional temperature sensors for measuring the temperature of external reference environment of said one or more battery packs;
providing a battery management system which converts the electrical output of said sensors into temperature readings, thus establishing a temperature profile of the battery pack during charge, discharge, or rest, said battery management system further including a memory, which memory contains a database of predefined normal operating profiles for said one or more battery packs over a variety of boundary conditions,
comparing said temperature profile of said one or more battery packs during charge, discharge, or rest with the healthy profile of said battery pack at the measured boundary condition; and,
issuing an alert should a sensor within the battery back detect an excursion from normal operating temperature during such charge, discharge, or rest.

12. The method of claim 10 wherein the boundary condition is selected from the group comprising operating temperature, pack voltage, pack charge or discharge rate, a sensor provided to monitor each of said selected boundary condition, and the appropriate look-up table or equation then used to assess battery health.
